(19) United States
(12) Patent Application Publication
(10) Pub. No.: US 2024/0414905 A1
(43) Pub. Date: Dec. 12, 2024

(54) BOARD INSPECTION DEVICE AND BOARD INSPECTION METHOD

(71) Applicant: CKD CORPORATION, Aichi (JP)

(72) Inventors: Kazuyoshi Kikuchi, Aichi (JP); Takuya Obata, Aichi (JP)

(73) Assignee: CKD CORPORATION, Aichi (JP)

(21) Appl. No.: 18/813,583

(22) Filed: Aug. 23, 2024

Related U.S. Application Data
(63) Continuation of application No. PCT/JP2022/025577, filed on Jun. 27, 2022.

(30) Foreign Application Priority Data
Mar. 7, 2022 (JP) 2022-034459

(51) Int. Cl. H05K 13/08; G06T 7/00; G06T 7/90; H05K 13/00

(52) U.S. Cl. CPC H05K 13/0818; G06T 7/001; G06T 7/90; H05K 13/0015; G06T 2207/10024; G06T 2207/30141; H05K 2203/0165; H05K 2203/161; H05K 2203/163

(57) ABSTRACT

Aboard inspection device includes: an imaging device that takes an image of an area on the board where the adhesive is applied; a CPU that specifies, by a first procedure, a center portion area of the adhesive in the image; specifies, by a second procedure, a foot portion area of the adhesive around the center portion area in the image; specifies an entire area of the adhesive based on the center portion area and the foot portion area; and based on the entire area of the adhesive, determines whether a quality of the adhesive is good or poor. The adhesive has a red color and is applied on a green resist area, and when specifying the foot portion area, the CPU extracts, an area of lower saturation than a predetermined saturation reference value from a saturation image based on the image.

### BACKGROUND

### Technical Field

The present disclosure relates to a board inspection device configured to perform an inspection on a board, such as a printed circuit board, and a board inspection method.

### Description of Related Art

In the case of mounting an electronic component on a printed circuit board, a general procedure first prints solder paste on an electrode pattern laid on the printed circuit board. The procedure then temporarily mounts an electronic component to the printed circuit board with the solder paste printed thereon by taking advantage of the viscosity of the solder paste. An adhesive (for example, a thermosetting adhesive) may additionally be applied on the printed circuit board, with a view to preventing the electronic component from being dropped off, for example, when the printed circuit board with the electronic component mounted thereon passes through a predetermined reflow furnace. After mounting of the electronic component, the printed circuit board is introduced to the reflow furnace and is subjected to a predetermined reflow process so as to implement soldering.

In a step prior to the reflow process, an inspection may be performed on the state of application of the adhesive. For example, a known inspection procedure with regard to the state of application of the adhesive specifies (extracts) an area occupied by the adhesive (actual adhesive area) from image data obtained by imaging the printed circuit board and then performs an inspection based on a positional relationship between the specified actual adhesive area and the solder paste or the like (as described in, for example, Patent Literature 1). Luminance data is one example of such image data.

A technique using color images is a known procedure of specifying (extracting) the area occupied by the adhesive (as described in, for example, Patent Literature 2). This technique compares a color image signal with a preset color distribution of the adhesive and specifies a part of the color image, which has the colors in the color distribution, as the area occupied by the adhesive.

### PATENT LITERATURE

Patent Literature 1: Japanese Patent No. 6262378B
Patent Literature 2: Japanese Patent No. H06-347419A

The adhesive is generally translucent. In the case where the application thickness of the adhesive is sufficiently large over the entire area, however, the area occupied by the adhesive is accurately specifiable by taking advantage of the color as described in Patent Literature 2.

The actual application thickness of the adhesive is, however, not constant or even over the entire area but is relatively small in an outer edge side portion (foot portion). Such a portion having a relatively small application thickness may be affected by a part located below the adhesive such as to have a color that is different from the color of a portion having a sufficiently large application thickness. The procedure that simply takes advantage of the color is thus likely to specify only the area having the sufficiently large application thickness, out of the actual area occupied by the adhesive. There is accordingly a possibility that the area occupied by the adhesive is not accurately specified.

### SUMMARY

By taking into account the circumstances described above, one or more embodiments of the present disclosure provide a board inspection device or the like that enables an area occupied by an adhesive to be specified with higher accuracy.

The following describes each of various aspects of the present disclosure. Functions and advantageous effects that are characteristic of each of the aspects are also described as appropriate.

Aspect 1. There is provided aboard inspection device configured to inspect an adhesive applied on a board. The board inspection device comprises an imaging device that takes an image of an area on the board where the adhesive is applied; and a central processing unit (CPU) that: specifies, by a first procedure, a center portion area of the adhesive in the image obtained by the imaging device, specifies, by a second procedure, a foot portion area of the adhesive around the center portion area in the image, specifies an entire area of the adhesive based on the center portion area and the foot portion area, and based on the entire area, determines whether a quality of the adhesive is good or poor.

In the configuration of above Aspect 1, the CPU specifies the center portion area of the adhesive in the image. The CPU further specifies the foot portion area (an area on an outer edge side) of the adhesive, which is generally thinner in thickness than the thickness of the center portion area, by the second specification procedure different from the first specification procedure employed for the center portion area. The CPU eventually specifies the entire area of the adhesive, based on the center portion area and the foot portion area that are specified respectively. As described above, the configuration of above Aspect 1 employs the different specification procedures to separately specify the center portion area and the foot portion area that respectively have different optical characteristics, and thereby enables both the center portion area and the foot portion area to be specified with high accuracy. This accordingly enables an area occupied by the adhesive to be specified with higher accuracy. As a result, this improves the accuracy of the good/poor quality judgment with regard to the adhesive (for example, good/poor quality judgment with regard to an application range of the adhesive and good/poor quality judgment with regard to a relative positional relationship of the adhesive to solder or the like).

Aspect 2. In the board inspection device described in above Aspect 1, the adhesive may have red color; and the CPU may be configured to extract a red color area from a hue image based on the image or to extract an area of higher luminance than a predetermined luminance reference value from a red luminance image based on the image, in a process of specifying the center portion area.

The red-color adhesive is generally and widely used. The configuration of above Aspect 2 enables the center portion area of such a red-color adhesive to be specified more accurately and more readily.

Aspect 3. In the board inspection device described in either above Aspect 1 or above Aspect 2, the board may have a green resist area; the adhesive may have red color and may be applied on the resist area; and the CPU may be configured to extract an area of lower saturation than a predetermined saturation reference value from a saturation image based on the image, in a process of specifying the foot portion area.

On the board with the red-color adhesive applied on the green resist area, a part having a relatively small application thickness of the adhesive is affected by the green resist area as the foundation to have relatively low saturation. By taking advantage of this feature, the configuration of above Aspect 3 extracts the area of low saturation from the saturation image based on the image, in the process of specifying the foot portion area. This configuration accordingly enables the foot portion area of the adhesive to be specified more accurately and more readily.

Aspect 4. In the board inspection device described in any one of above Aspects 1 to 3, the CPU may be configured to execute a process of excluding an area of a silkscreen provided on the board, from at least one of the center portion area, the foot portion area, and the entire area that are eventually specified.

The phrase “(areas) eventually specified” denotes the center portion area eventually specified by the center portion specification unit, the foot portion area eventually specified by the foot portion specification unit, and the entire area eventually specified by the entirety specification unit.

The configuration of above Aspect 4 more reliably prevents an area of a silkscreen (a printed portion that is printed on the board and that indicates information including letters, characters, symbols, signs and the like) from being mistakenly specified as the area with regard to the adhesive (the center portion area, the foot portion area or the entire area). This configuration accordingly enables the area with regard to the adhesive to be specified with higher accuracy.

Aspect 5. There is provided a board inspection method of inspecting an adhesive applied on a board. The board inspection method comprises an imaging process of taking an image of an area on the board where the adhesive is applied; a center portion specification process of specifying, by a first procedure, a center portion area of the adhesive in the image obtained by the imaging process; a foot portion specification process of specifying, by a second procedure, a foot portion area of the adhesive around the center portion area in the image; an entirety specification process of specifying an entire area of the adhesive based on the center portion area and the foot portion area; and a determination process of determining, based on the entire area, a quality of the adhesive is good or poor.

The configuration of above Aspect 5 has similar functions and advantageous effects to those of Aspect 1 described above. The technical features with regard to any of above Aspects 2 to 4 may be applied to the configuration of above Aspect 5.

### BRIEF DESCRIPTION OF DRAWINGS

FIG. 1 is a partly enlarged schematic plan view illustrating the schematic configuration of a printed circuit board;

FIG. 2 is a partly enlarged schematic sectional view illustrating the printed circuit board;

FIG. 3 is a block diagram illustrating the configuration of a production line of the printed circuit board;

FIG. 4 is a schematic configuration diagram schematically illustrating a board inspection device;

FIG. 5 is a block diagram illustrating the functional configuration of the board inspection device;

FIG. 6 is a block diagram illustrating the functional configuration of an adhesive inspection unit;

FIG. 7 is a diagram simply illustrating a color circle in an HSV color space;

FIG. 8 is a flowchart showing a center portion specification process;

FIG. 9 is a diagram illustrating one example of a hue image;

FIG. 10 is a diagram illustrating one example of a center portion extraction image;

FIG. 11 is a flowchart showing a foot portion specification process;

FIG. 12 is a diagram illustrating one example of a saturation image;

FIG. 13 is a diagram illustrating one example of a reverse saturation image;

FIG. 14 is a diagram illustrating one example of a binarized reverse saturation image;

FIG. 15 is a diagram illustrating one example of a binarized reverse brightness image;

FIG. 16 is a diagram illustrating one example of a foot portion extraction image;

FIG. 17 is a diagram illustrating one example of an adhesive extraction image;

FIG. 18 is a schematic plan view illustrating an inspection of an adhesive alone;

FIG. 19 is a schematic plan view illustrating an inspection on a positional relationship between solder and an adhesive;

FIG. 20 is a schematic plan view illustrating an inspection on a positional relationship between an adhesive portion and a planned location area of an electrode portion;

FIG. 21 is a flowchart showing the center portion specification process according to one or more embodiments;

FIG. 22 is a diagram illustrating one example of a red luminance image;

FIG. 23 is a diagram illustrating one example of a binarized red luminance image;

FIG. 24 is a diagram illustrating one example of a binarized saturation image;

FIG. 25 is a diagram illustrating one example of the center portion extraction image according to one or more embodiments;

FIG. 26 is a diagram illustrating one example of an adhesive and silkscreen extraction image;

FIG. 27 is a flowchart showing a silkscreen area exclusion process according to one or more embodiments;

FIG. 28 is a diagram illustrating one example of a brightness image;

FIG. 29 is a diagram illustrating one example of a binarized brightness image;

FIG. 30 is a diagram illustrating one example of a silkscreen image;

FIG. 31 is a diagram illustrating one example of a reverse silkscreen image; and

FIG. 32 is a diagram illustrating one example of an adhesive portion extraction image according to one or more embodiments.

### DETAILED DESCRIPTION OF EMBODIMENTS

The following describes embodiments with reference to drawings. The configuration of a printed circuit board as a board is described first.

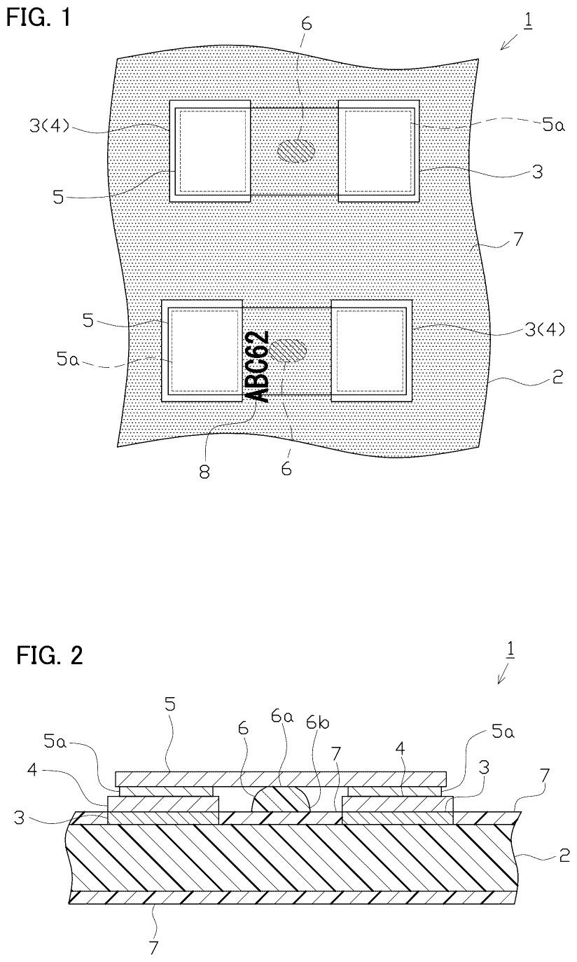

As shown in FIG. 1 and FIG. 2, a printed circuit board 1 (hereinafter simply referred to as ‘board 1’) is configured by forming lands 3 made of copper foil, a predetermined electrode pattern (not shown) and the like on a flat plate-like base substrate 2 made of, for example, a glass epoxy resin. Solder paste 4 (hereinafter simply referred to as ‘solder 4’) obtained by kneading solder particles with flux is printed on the lands 3.

Electronic components 5 such as chips are mounted on the solder 4. More specifically, each electronic component 5 has a plurality of electrode portions 5a configured by electrodes, leads and the like. Each of the electrode portions 5a is joined with a predetermined portion of the solder 4.

According to one or more embodiments, the electronic component 5 that is fixed by the solder 4 is additionally bonded by means of an adhesive (shown as an area filled with slant lines in FIG. 1), with a view to strengthening the fixation. The adhesive 6 is an insulating adhesive material having the thermosetting property. The adhesive 6 is a liquid that displays a red color, that is translucent, and that has viscosity at least in the state prior to curing. In planar view of the board 1, the adhesive 6 is configured to include a center portion 6a and a foot portion 6b located around the center portion 6a. In the state prior to mounting of the electronic component 5, in general, the thickness of application in the center portion 6a is relatively large, while the thickness of application in the foot portion 6b, which is located on an outer edge side of the adhesive 6, is relatively small.

A green resist area 7 (shown as an area filled with a dotted pattern in FIG. 1) is provided in a location other than the lands 3 on the surface of the base substrate 2. The resist area 7 is made of an insulating resist and serves to coat the base substrate 2 and the electrode pattern described above. According to one or more embodiments, the adhesive 6 is applied on the resist area 7.

Furthermore, a silkscreen 8, which is a printed portion where pieces of information including letters, characters, signs, symbols and the like are printed, is provided in the resist area 7. The color of the silkscreen 8 is generally white or yellow and is white according to one or more embodiments.

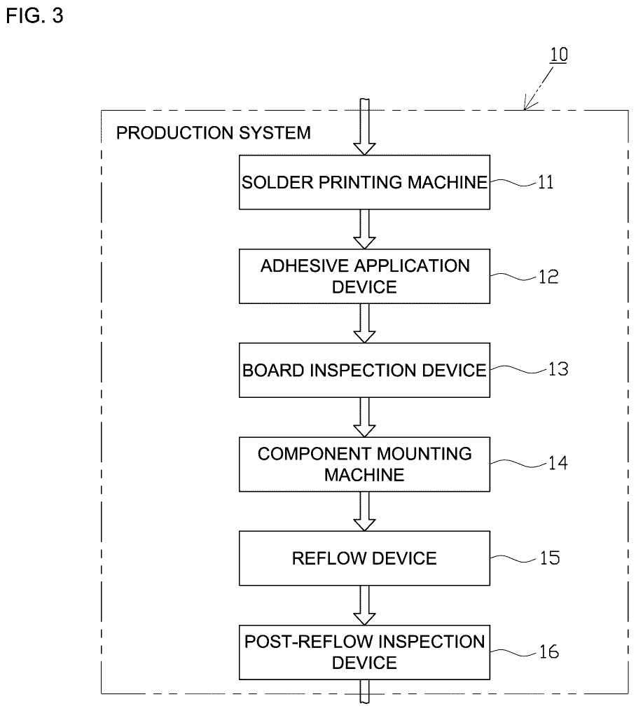

A production line (production process) of manufacturing the printed circuit board 1 is described next. As shown in FIG. 3, a production line 10 includes a solder printing machine 11, an adhesive application device 12, a board inspection device 13, a component mounting machine 14, a reflow device 15 and a post-reflow inspection device 16, which are located sequentially from an upstream side thereof (from an upper side in FIG. 3). The board 1 is set to be transferred in this sequence to these devices and machines.

The solder printing machine 11 is configured to print predetermined amounts of the solder 4 at predetermined positions (for example, on the lands 3) of the board 1. More specifically, the solder printing machine 11 is provided with a metal screen (not shown) that includes a plurality of holes formed at positions corresponding to the lands 3 and the like on the board 1 and serves to screen-print the solder 4 on the board 1 by using the metal screen.

The adhesive application device 12 is configured to apply predetermined amounts of the adhesive 6 at predetermined positions (for example, at positions where the electronic components 5 are to be placed) on the board 1. The adhesive application device 12 is provided with, for example, a nozzle head (not shown) that is movable in X-Y directions and serves to eject the adhesive 6 from the nozzle head and thereby apply the adhesive 6 in the resist area 7.

The board inspection device 13 is configured to perform an inspection on the adhesive 6 that is applied. The board inspection device 13 also has an inspecting function of performing an inspection on the state of the solder 4 that is printed and on the presence or the absence of any foreign substance on the board 1. The board inspection device 13 will be described more in detail later.

The component mounting machine 14 is configured to perform a component mounting process (mounting process) that mounts the electronic components 5 on the lands and the like where the solder 4 is printed. This causes the respective electrode portions 5a of the electronic components 5 to be temporarily mounted to predetermined portions of the solder 4.

The reflow device 15 is configured to heat and melt the solder 4 and to heat and cure the adhesive 6. On the board 1 subjected to a reflow process by the reflow device 15, the land 3 is joined with the electrode portion 5a of the electronic component 5 by means of the solder 4, and the electronic component 5 is firmly fixed by means of the adhesive 6.

The post-reflow inspection device 16 is configured to perform a post-reflow inspection process that determines, for example, whether solder joint is appropriately performed in the reflow process. The post-reflow inspection process uses, for example, image data of the board 1 after the reflow process to determine whether there is any positional misalignment in the electronic component 5.

The production line 10 additionally includes conveyors or the like provided between the respective devices described above, for example, between the solder printing machine 11 and the adhesive application device 12, and configured to transfer the board 1, although not being specifically illustrated. The production line 10 also includes branching units between the board inspection device 13 and the component mounting machine 14 and on a downstream side of the post-reflow inspection device 16. The board 1 that is determined to be non-defective by the board inspection device 13 and by the post-reflow inspection device 16 is guided directly to a downstream side, whereas the board 1 that is determined to be defective by either of the inspection devices 13 and 16 is discharged by the branching unit to a defective storage unit (not shown).

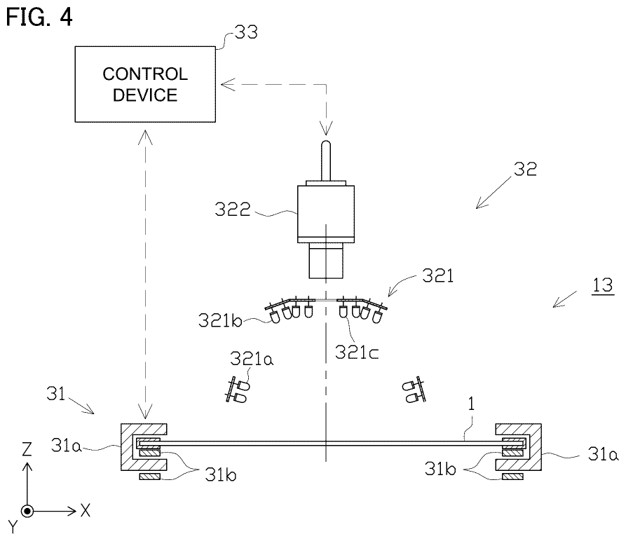

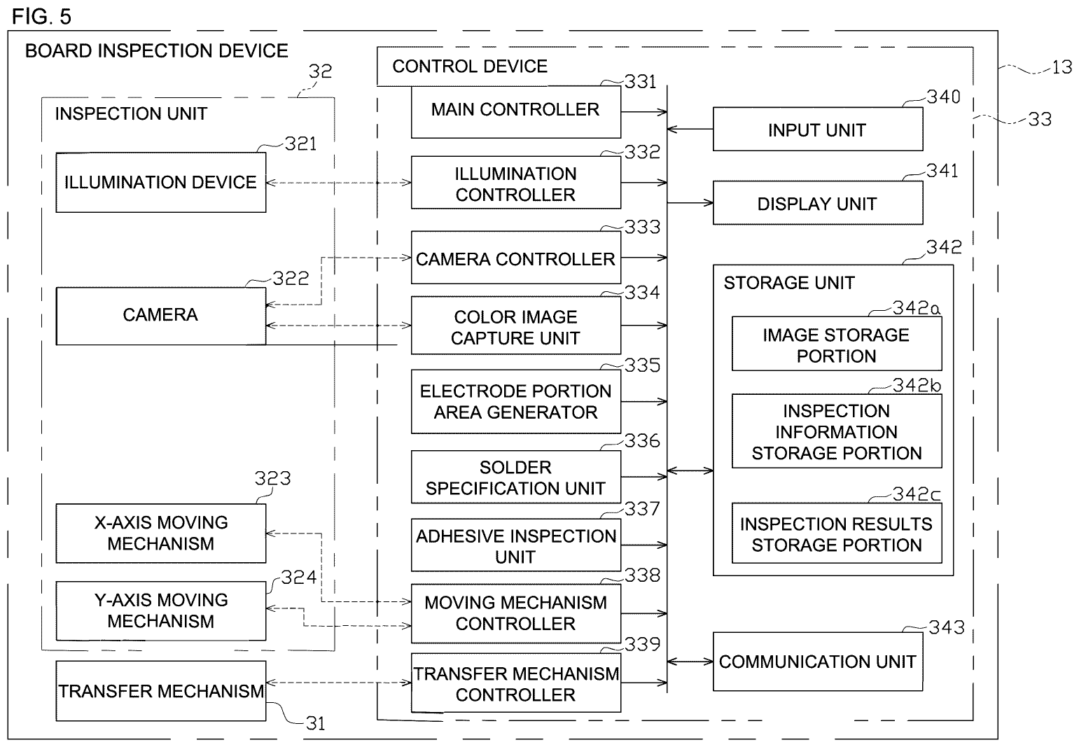

The following describes the configuration of the board inspection device 13. As shown in FIG. 4 and FIG. 5, the board inspection device 13 includes a transfer mechanism 31 configured to perform transfer, positioning and the like of the board 1; an inspection unit 32 configured to perform an inspection of the board 1; and a control device 33 configured to drive and control the transfer mechanism 31 and the inspection unit 32 and to perform various controls, image processing and arithmetic processing in the board inspection device 13.

The transfer mechanism 31 includes a pair of transfer rails 31a placed along a carry in/out direction of the board 1; and an endless conveyor belt 31b arranged such as to be rotatable relative to the respective transfer rails 31a. The transfer mechanism 31 is also provided with a drive unit, such as a motor, configured to drive the conveyor belt 31b and a chuck mechanism configured to position the board 1 at a predetermined position, although these components are not specifically illustrated. The transfer mechanism 31 is driven and controlled by the control device 33 (more specifically, by a transfer mechanism controller 339 described later).

Under the configuration described above, when the board 1 is carried into the board inspection device 13, respective side edge portions of the board 1 in a width direction that is perpendicular to the carry in/out direction, are inserted into the respective transfer rails 31a, and the board 1 is placed on the conveyor belt 31b. The conveyor belt 31b subsequently starts operation to transfer the board 1 to a predetermined inspection position. When the board 1 reaches the inspection position, the conveyor belt 31b stops and the chuck mechanism is actuated. Such actuation of the chuck mechanism presses up the conveyor belt 31b and causes the respective side edge portions of the board 1 to be placed between the conveyor belt 31b and respective upper sides of the transfer rails 31a. This positions and fixes the board 1 at the inspection position. On completion of the inspection, the fixation by the chuck mechanism is released and the conveyor belt 31b starts operation. The board 1 is accordingly carried out from the board inspection device 13. The configuration of the transfer mechanism 31 is naturally not limited to the configuration of the embodiments described above, but another configuration may be employable.

The inspection unit 32 is placed above the transfer rails 31a (above the transfer path of the board 1). The inspection unit 32 includes an illumination device 321 and a camera 322. According to one or more embodiments, the camera 322 configures the “imaging unit” or “imaging device”.

The inspection unit 32 also includes an X-axis moving mechanism 323 that allows for moves in an X-axis direction (left-right direction in FIG. 4); and a Y-axis moving mechanism 324 that allows for moves in a Y-axis direction (front-rear direction in FIG. 4). Both the moving mechanisms 323 and 324 are driven and controlled by the control device 33 (more specifically, by a moving mechanism controller 338 described later).

The illumination device 321 is configured to irradiate the board 1, which is an inspection object by the board inspection device 13, with predetermined light. More specifically, the illumination device 321 includes a first ring light 321a, a second ring light 321b and a third ring light 321c (as shown in FIG. 4).

The first ring light 321a is configured to irradiate the board 1 with light emitted from an approximately horizontal direction. The second ring light 321b is placed above the first ring light 321a and is configured to irradiate the board 1 with light emitted obliquely downward. The third ring light 321c is placed on an inner side of the second ring light 321b and is configured to irradiate the board 1 with light emitted downward from an approximately vertical direction.

Each of the ring lights 321a, 321b and 321c irradiates the board 1 with white light. More specifically, each of the ring lights 321a, 321b and 321c irradiates the board 1 simultaneously with a plurality of color lights, i.e., red light, blue light and green light.

The camera 322 is located such that an optical axis thereof is extended in a vertical direction (a Z-axis direction) and is configured to take an image of a predetermined inspection target area on the board 1, which is the inspection object, from directly above. The “inspection target area” of the board 1 denotes one area among a plurality of areas set in advance on the board 1 with the size of an imaging field (imaging range) of the camera 322 as one unit.

The camera 322 is configured by a color camera and is operated and controlled by the control device 33 (more specifically, by a camera controller 333 described later). The operation control of the control device 33 causes the camera 322 to take an image of an inspection target area, which includes at least an area where the adhesive 6 is applied, on the board 1, in the state that the board 1 is simultaneously irradiated with the lights from the respective ring lights 321a, 321b and 321c. An RGB luminance image with regard to the inspection target area is accordingly obtained. This RGB luminance image has a large number of pixels, and three different parameter values with regard to R (red), G (green) and B (blue) are set corresponding to each of the pixels. According to one or more embodiments, these parameter values are expressed in a range of 0 to 1. The process of taking an image of at least the area where the adhesive 6 is applied on the board 1 by the camera 322 corresponds to the “imaging process”. The RGB luminance image corresponds to the “taken image”.

The RGB luminance image obtained by the camera 322 is transferred to the control device 33 (more specifically, to a color image capture unit 334 described later). The control device 33 performs an inspection process with regard to the adhesive 6, based on this RGB luminance image.

The control device 33 is configured by a computer including, for example, a CPU (Central Processing Unit) that performs predetermined arithmetic operations; a ROM (Read Only Memory) that stores a variety of programs, fixed value data and the like; a RAM (Random Access Memory) that temporarily stores various data in the course of execution of the various arithmetic operations; and peripheral circuits of the foregoing.

The CPU operates according to the variety of programs, so that the control device 33 serves as a variety of function parts, for example, a main controller 331, an illumination controller 332, a camera controller 333, a color image capture unit 334, an electrode portion area generator 335, a solder specification unit 336, an adhesive inspection unit 337, a moving mechanism controller 338 and a transfer mechanism controller 339.

The respective function parts described above are, however, implemented by cooperation of the various hardware components, such as the CPU, the ROM and the RAM. There is no need to clearly distinguish the functions implemented by the hardware configuration and the functions implemented by the software configuration from each other. Part or the entirety of these functions may be implemented by a hardware circuit, such as an IC. The control device 33 also includes a function part configured to perform an inspection on the state of the solder 4 and on the presence or the absence of any foreign substance on the board 1. The explanation on this function part is, however, omitted from the description of the embodiments.

The control device 33 is further provided with an input unit 340 that is configured by a keyboard and a mouse, a touch panel or the like; a display unit 341 configured by a liquid crystal display or the like and provided with a display screen; a storage unit 342 configured to store a variety of data and programs, the results of arithmetic operations, the results of an inspection, and the like; and a communication unit 343 configured to send and receive a variety of data from and to outside. The storage unit 342 and the communication unit 343 are described first.

The storage unit 342 is configured by, for example, an HDD (Hard Disk Drive) or an SSD (Solid State Drive) to store various pieces of information. The storage unit 342 includes an image storage portion 342a, an inspection information storage portion 342b and an inspection results storage portion 342c.

The image storage portion 342a is configured to store the RGB luminance image taken and obtained by the camera 322. The image storage portion 342a also stores a variety of images including hue images and saturation images, which are respectively described later. Each of the images stored in the image storage portion 342a is allowed to be displayed on the display unit 341 as appropriate.

The inspection information storage portion 342b is configured to store various pieces of information used for an inspection of the board 1. The inspection information storage portion 342b stores, for example, a variety of reference values and threshold values used when an image is processed by a binarization process or when an image is subjected to good/poor quality judgment, as well as design data and manufacturing data. The design data and the manufacturing data include, for example, planned application positions of the adhesive 6, the dimensions of the adhesive 6 in an ideal application state (for example, the area, the contour length and the volume of the adhesive 6), and various pieces of information with regard to the electronic components 5 including the size and a planned location area of each of the electrode portions 5a.

The inspection results storage portion 342c is configured to store inspection results data by the adhesive inspection unit 337. The inspection results storage portion 342c also stores, for example, inspection results data with regard to the state of the solder 4 and with regard to the presence or the absence of any foreign substance on the board 1, as well as statistical data obtained by stochastically and statistically processing the variety of inspection results data. Each of these inspection results data and these statistical data is allowed to be displayed on the display unit 341 as appropriate.

The communication unit 343 is provided with, for example, a communication interface in conformity with a communication standard such as a wired LAN (Local Area network) or a wireless LAN and is configured to send and receive a variety of data to and from the outside. For example, the results of an inspection performed by the adhesive inspection unit 337 are output to the outside via the communication unit 343, and the results of an inspection performed by the post-reflow inspection device 16 are input via the communication unit 343.

The following describes the above respective function parts of the control device 33 in detail. The moving mechanism controller 338 and the transfer mechanism controller 339 are described first, and the main controller 331 and the like are subsequently described.

The moving mechanism controller 338 is a function part of driving and controlling the X-axis moving mechanism 323 and the Y-axis moving mechanism 324 and is configured to control the position of the inspection unit 32, in response to a command signal from the main controller 331. The moving mechanism controller 338 drives and controls the X-axis moving mechanism 323 and the Y-axis moving mechanism 324 to move the inspection unit 32 to a position above an arbitrary inspection target area on the board 1 that is positioned and fixed at an inspection position. While the inspection unit 32 is sequentially moved to each of a plurality of inspection target areas set on the board 1, an inspection with regard to each of the inspection target areas is performed. This accordingly performs an inspection on the entire area of the board 1.

The transfer mechanism controller 339 is a function part of driving and controlling the transfer mechanism 31 and is configured to control the transfer position of the board 1, in response to a command signal from the main controller 331.

The following describes the main controller 331 and the like. The main controller 331 is a function part of controlling the entire board inspection device 13 and is configured to send and receive a variety of signals to and from the other function parts including the illumination controller 332 and the camera controller 333.

The illumination controller 332 is a function part of driving and controlling the illumination device 321. The illumination controller 332 is configured to perform the timing control with regard to emission of light from the illumination device 321 to the board 1 and with regard to a stop of the emission, in response to command signals from the main controller 331.

The camera controller 333 is a function part of driving and controlling the camera 322. The camera controller 333 is configured to control, for example, the imaging timing of the board 1 by the camera 322, in response to a command signal from the main controller 331.

The color image capture unit 334 is a function part of capturing the RGB luminance image taken and obtained by the camera 322. The RGB luminance image captured by the color image capture unit 334 is stored in the image storage portion 342a.

The electrode portion area generator 335 is configured to generate an electrode portion area Adh (shown in FIG. 20) that indicates a planned location area of the electrode portion 5a of the electronic component 5. According to one or more embodiments, the electrode portion area generator 335 basically generates a planned location area of the electrode portion 5a on the design data or the manufacturing data, as the electrode portion area Adh. In the case where an actual area that is occupied by the actual solder 4 (a solder area Ajh described below) is deviated from an ideal area that is occupied by the ideal solder 4, the electrode portion area generator 335 adjusts the electrode portion area Adh according to this deviation.

The solder specification unit 336 is configured to specify an area occupied by the solder 4 (hereinafter referred to as “solder area Ajh”) on the board 1, based on the RGB luminance image obtained by the camera 322. More specifically, the solder specification unit 336 performs, for example, a binarization process that uses a predetermined luminance value set in advance for the RGB luminance image, as a reference value, so as to specify the solder area Ajh that denotes a plane area occupied by the solder 4. A modified configuration of the solder specification unit 336 may set a search area corresponding to a planned application position of the solder 4 and may exclude a plane area of the solder 4 having an extremely small area from the solder area Ajh, based on a ratio of the area of the solder 4 located in the search area to the entire area of the search area.

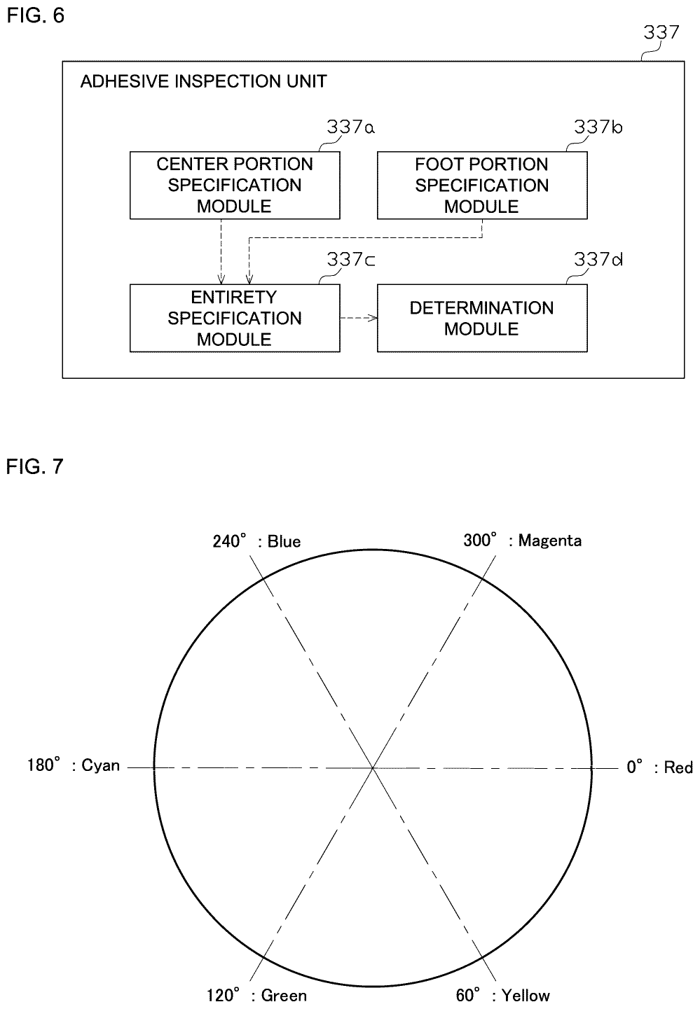

The adhesive inspection unit 337 is configured to perform an inspection on the adhesive 6 applied on the board 1. As shown in FIG. 6, the adhesive inspection unit 337 has various function modules including a center portion specification module 337a, a foot portion specification module 337b, an entirety specification module 337c and a determination module 337d. According to one or more embodiments, the center portion specification module 337a configures the “center portion specification unit”. Similarly, the foot portion specification module 337b, the entirety specification module 337c and the determination module 337d respectively configure the “foot portion specification unit”, the “entirety specification unit”, and the “determination unit”.

The center portion specification module 337a is configured to perform a center portion specification process that specifies a center portion area Ajsa (shown in FIG. 10), which is an area corresponding to the center portion 6a, in the RGB luminance image described above.

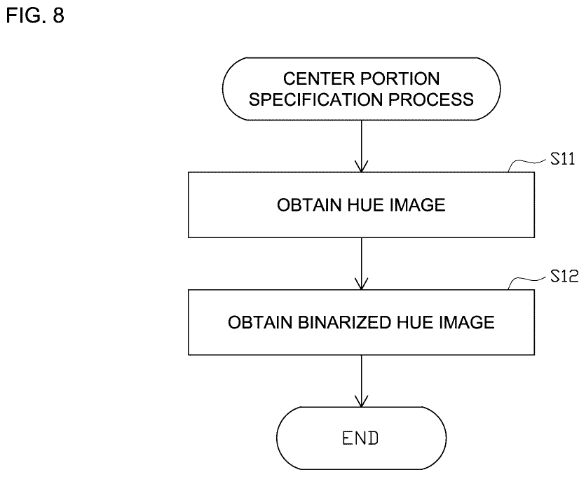

As shown in FIG. 8, at step S11, the center portion specification process first obtains a hue mage with regard to the inspection target area of the board 1 by using the RGB luminance image obtained by the camera 322. More specifically, the center portion specification process calculates a hue ‘Hue’ (hereinafter referred to as “hue H”) of each pixel in a color circle of an HSV color space with setting 0 degree (360 degrees) as red, 60 degrees as yellow, 120 degrees as (strict) green, 180 degrees as cyan, 240 degrees as blue, and 300 degrees as magenta (as shown in FIG. 7), and obtains a hue image where the hue H is correlated to each of the pixels. The hue image is stored in the image storage portion 342a.

The hue H is calculated by using Mathematical Expression 1, Mathematical Expression 2 or Mathematical Expression 3 given below. Mathematical Expression 1 is used in the case where a parameter value of B is maximum among respective parameter values with regard to R, G, and B. Mathematical Expression 2 is used in the case where a parameter value of R is maximum among the respective parameter values with regard to R, G and B. Mathematical Expression 3 is used in the case where a parameter value of G is maximum among the respective parameter values with regard to R, G and B. The hue H is not defined when a maximum value and a minimum value of the respective parameter values with regard to R, G, and B are equal to each other:

$$H = 60 \times ( G - R ) / ( MAX - MIN ) + 60 \qquad < Mathematical Expression 1 >$$

$$H = 60 \times ( B - G ) / ( MAX - MIN ) + 180 \qquad < Mathematical Expression 2 >$$

$$H = 60 \times ( R - B ) / ( MAX - MIN ) + 300 \qquad < Mathematical Expression 3 >$$

In Mathematical Expressions 1 to 3, R, G and B respectively denote the parameter values with regard to R, with regard to G and with regard to B; MAX represents the maximum value among the respective parameter values; and MIN represents the minimum value among the respective parameter values.

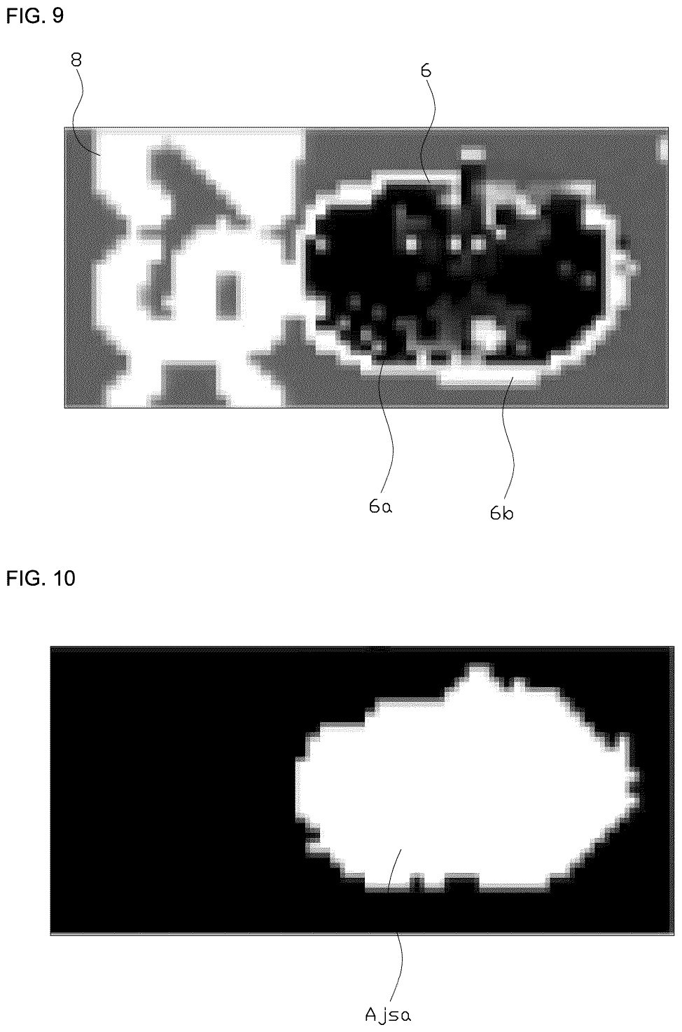

The hue image denotes an image indicating the hues of the respective pixels of the RGB luminance image in the color circle of the HSV color space. FIG. 9 illustrates one example of the hue image. The hue image includes, for example, the adhesive 6 and the silkscreen 8.

In the RGB luminance image, while the center portion 6a having a relatively large application thickness has red color, the foot portion 6b having a relatively small application thickness is affected by the green resist area 7 as the foundation and has a color close to black color. Accordingly, in the obtained hue image, the center portion 6a is relatively dark, while the foot portion 6b is relatively bright (as shown in FIG. 9). In the hue image, the silkscreen 8 is relatively bright.

After obtaining the hue image, at step S12, the center portion specification process subsequently processes the hue image by a binarization process using a predetermined hue reference value, in order to extract a red color area (i.e., an area including the center portion 6a) from the hue image, and thereby obtains a center portion extraction image. FIG. 10 illustrates one example of the center portion extraction image. The hue reference value is set, based on the hue of the center portion 6a in the hue image.

The center portion extraction image is a black and white image including 0 (bright part) and 1 (dark part) and is stored in the image storage portion 342a. According to one or more embodiments, the bright part of the center portion extraction image corresponding to the red color area in the hue image is specified as the center portion area Ajsa (shown in FIG. 10). In the case of specifying the center portion area Ajsa, a filling process or the like may be performed to eliminate isolated points. In the case where another red color area other than the red color area of the adhesive 6 is present in the RGB luminance image, an elimination process of eliminating this another red color area may be performed, based on the design data or the manufacturing data, with a view to excluding this red color area from the center portion area Ajsa.

The foot portion specification module 337b is configured to perform a foot portion specification process that specifies a foot portion area Ajsb, which is an area located around the center portion area Ajsa and corresponds to the foot portion 6b of the adhesive 6, in the RGB luminance image. The foot portion specification process specifies the foot portion area Ajsb by a specification procedure that is different from the specification procedure of the center portion area Ajsa by the center portion specification module 337a.

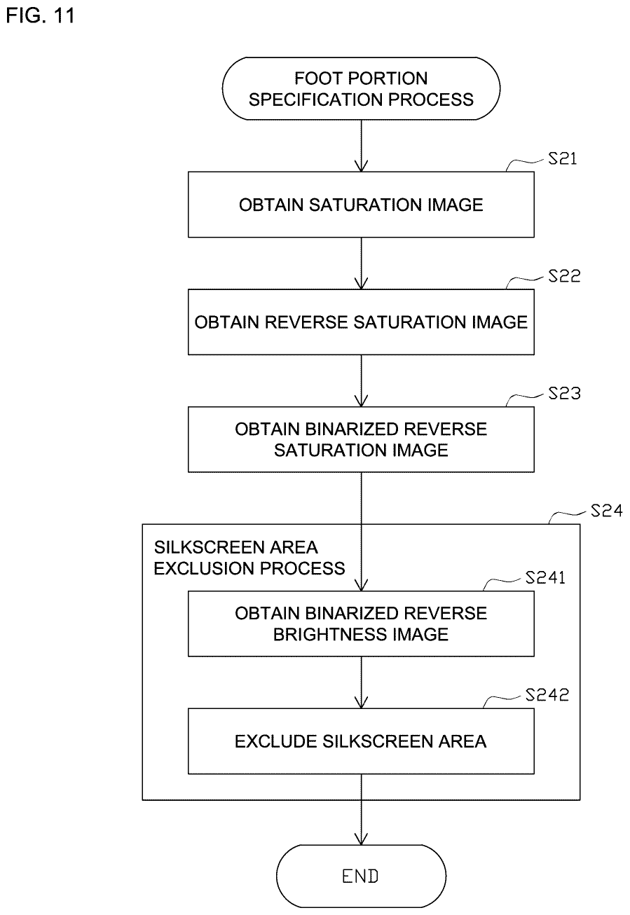

As shown in FIG. 11, at step S21, the foot portion specification process first obtains a saturation image with regard to the inspection target area of the board 1 by using the RGB luminance image stored in the image storage portion 342a. More specifically, the foot portion specification process uses Mathematical Expression 4 given below to calculate a saturation S (saturation in the HSV system) of each of the pixels in the RGB luminance image and obtains a saturation image where the saturation S is correlated to each of the pixels. The saturation image is stored in the image storage portion 342a:

$$S = ( 1 - 3 \times MIN / ( R + G + B ) ) \qquad < Mathematical Expression 4 >$$

Like Mathematical Expressions 1 to 3, in Mathematical Expression 4, R, G and B respectively denote the parameter values with regard to R, G and B; and MIN represents the minimum value among the respective parameter values. The saturation S of each pixel in the saturation image is expressed in a range of 0 to 1. The saturation S of the pixel closer to 1 means that the color of the pixel is closer to the primary color. The saturation S may be calculated by Mathematical Expression 4a given below, in place of Mathematical Expression 4.

$$S = ( MAX - MIN ) / MAX \qquad < Mathematical Expression 4 a >$$

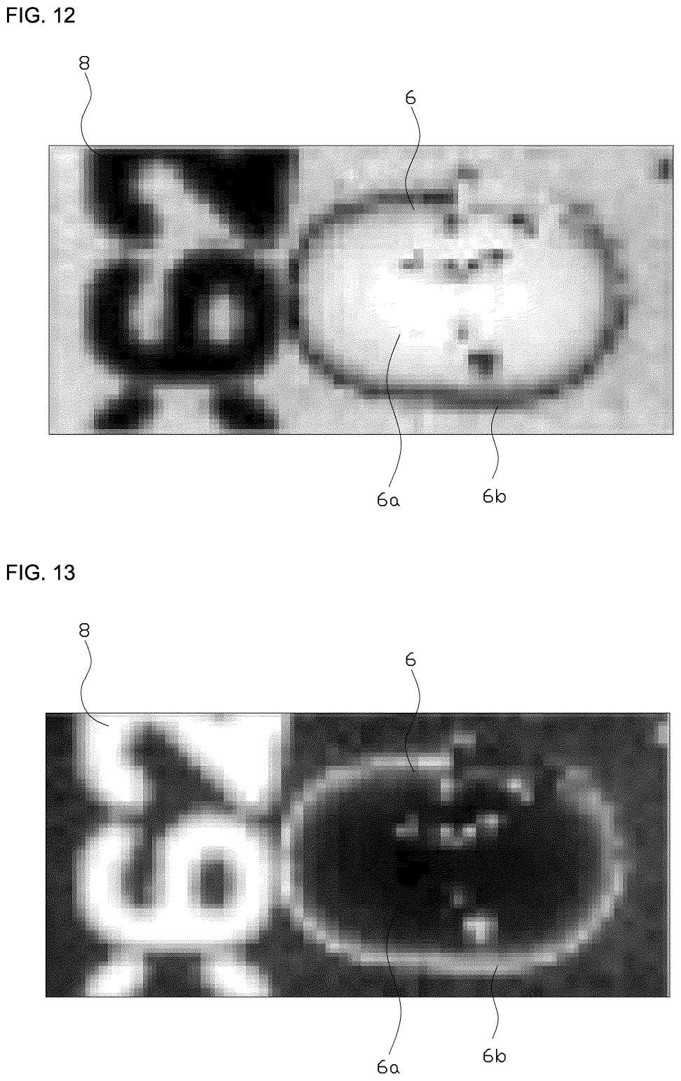

The saturation image denotes an image indicating the saturations of the respective pixels in the RGB luminance image. FIG. 12 illustrates one example of the saturation image. The saturation image includes, for example, the adhesive 6 and the silkscreen 8.

In the RGB luminance image, the foot portion 6b having a relatively small application thickness is affected by the green resist area 7 as the foundation and has low saturations. Accordingly, in the obtained saturation image, the foot portion 6b is relatively dark (as shown in FIG. 12). In the saturation image, the silkscreen 8 is also relatively dark. The center portion 6a and the resist area 7 are, on the other hand, relatively bright in the saturation image.

At step S22, the foot portion specification process obtains a reverse saturation image by reversing the saturation image, in order to extract an area of relatively low saturations (i.e., an area including the foot portion 5b) from the saturation image. FIG. 13 illustrates one example of the reverse saturation image. In the reverse saturation image, the foot portion 6b and the silkscreen 8 are relatively bright.

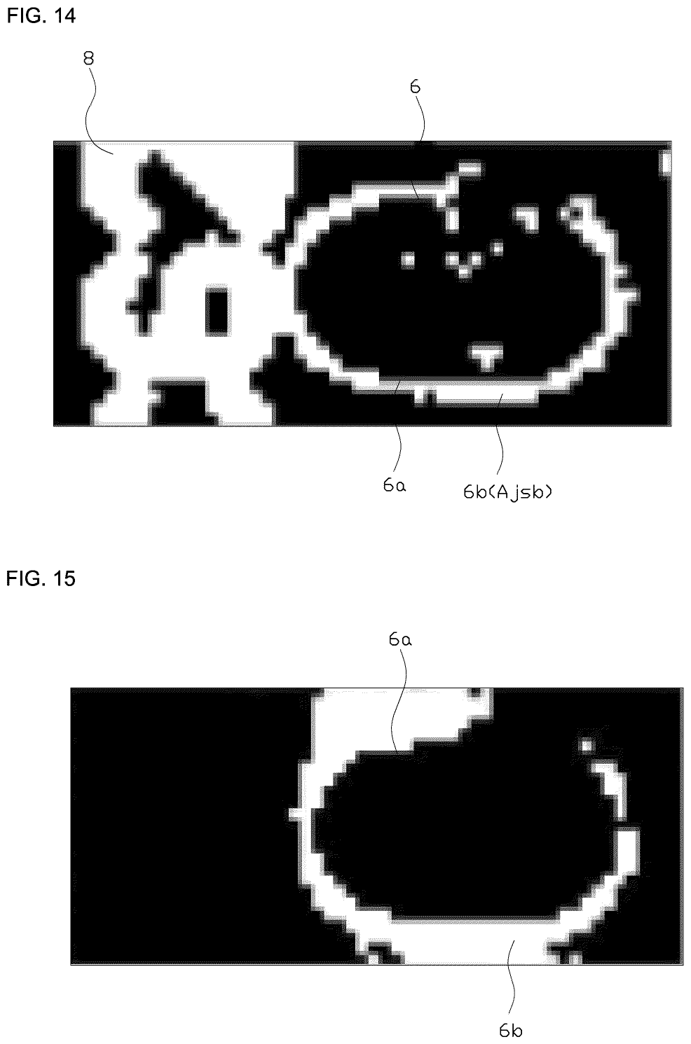

After step S22, the foot portion specification process subsequently processes the reverse saturation image by a binarization process using a predetermined saturation reference value and thereby obtains a binarized reverse saturation image at step S23. FIG. 14 illustrates one example of the binarized reverse saturation image. The binarized reverse saturation image is a black and white image including 0 (bright part) and 1 (dark part) and is stored in the image storage portion 342a. In the binarized reverse saturation image, not only the foot portion 6b but the silkscreen 8 is a bright part. The saturation reference value is set, based on the respective saturations of the foot portion 6b and the resist area 7 in the binarized reverse saturation image.

At step S24, the foot portion specification process subsequently performs a silkscreen area exclusion process to exclude an area with regard to the silkscreen 8 from the binarized reverse saturation image. The silkscreen area exclusion process first obtains a binarized reverse brightness image based on the RGB luminance image, in order to extract an area of especially low brightness (value) from the RGB luminance image, at step S241. A procedure of obtaining the binarized reverse brightness image first uses Mathematical Expression 5 given below to calculate a value V (brightness in the HSV system) of each pixel in the RGB luminance image and thereby obtains a brightness image where the value V is correlated to each of the pixels. The brightness image denotes an image indicating the brightness of each pixel in the RGB luminance image;

$$V = MAX \qquad < Mathematical Expression 4 >$$

Like Mathematical Expressions 1 to 3, in Mathematical Expression 5, MAX represents the maximum value among the respective parameter values with regard to R, G, and B.

The procedure then processes the brightness image by a reversing process and a binarization process and thereby obtains a binarized reverse brightness image. FIG. 15 illustrates one example of the binarized reverse brightness image. In the course of this binarization process, a brightness reference value is used to exclude (not to extract) an area with regard to the silkscreen 8 but to extract an area with regard to the foot portion 6b. With a view to more certainly excluding the area with regard to the silkscreen 8, an additional process may be performed separately to obtain a silkscreen image described later (shown in FIG. 30) and to exclude the area with regard to the silkscreen 8 from the binarized reverse brightness image by using the silkscreen image.

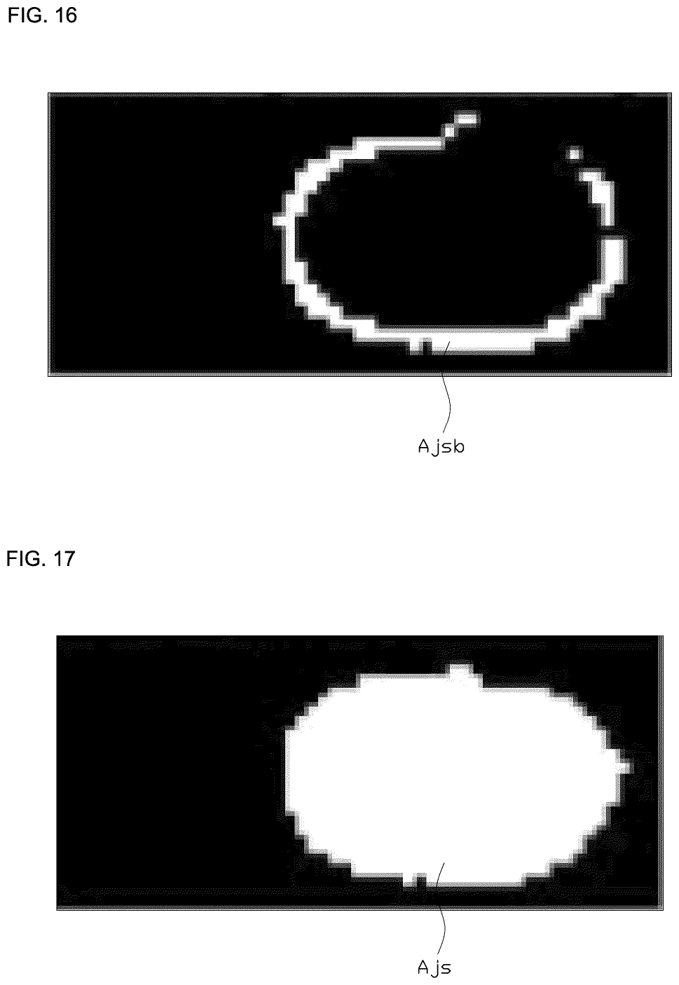

At step S242, the silkscreen area exclusion process calculates a logical AND of the obtained binarized reverse saturation image and the obtained binarized reverse brightness image, so as to exclude the area with regard to the silkscreen 8 from the binarized reverse saturation image. The foot portion specification process accordingly obtains a foot portion extraction image. FIG. 16 illustrates one example of the foot portion extraction image. The foot portion extraction image is a black and white image including 0 (bright part) and 1 (dark part) and is stored in the image storage portion 342a. According to one or more embodiments, the bright part in the foot portion extraction area is specified as the foot portion area Ajsb.

In the case of specifying the foot portion area Ajsb, a modified configuration may separately perform a process of excluding areas with regard to the lands 3 and the electrode pattern, which are expected to have relatively low saturations. For example, this process may refer to the positions of the lands 3 and the like in the design data or the manufacturing data and exclude areas of low saturations located at the referred positions from the binarized reverse saturation image.

The entirety specification module 337c is configured to perform an entirety specification process that specifies an entire area Ajs of the adhesive 6 (shown in FIG. 17), based on the center portion area Ajsa specified by the center portion specification module 337a and the foot portion area Ajsb specified by the foot portion specification module 337b. The entirety specification process calculates a logical AND of the center portion extraction image and the foot portion extraction image, so as to obtain an adhesive extraction image. FIG. 17 illustrates one example of the adhesive extraction image. The adhesive extraction image is a black and white image including 0 (bright part) and 1 (dark part) and is stored in the image storage portion 342a. According to one or more embodiments, the bright part in the adhesive extraction image is specified as the entire area Ajs.

In the case of obtaining the adhesive extraction image, when there is any isolated point (dark part) between the center portion area Ajsa and the foot portion area Ajsb, a filling process (a process that deals with the isolated point as a bright part) may be performed to fill the isolated point.

As described above, the configuration of the embodiments performs the process of taking an image of the board 1 by using the camera 322 (the imaging process), the center portion specification process, the foot portion specification process and the entirety specification process, so as to eventually specify the entire area Ajs. Performing the respective processes described above with regard to all the inspection target areas on the board 1 as the object specifies the entire areas Ajs with regard to all the portions of the adhesive 6 provided on the board 1.

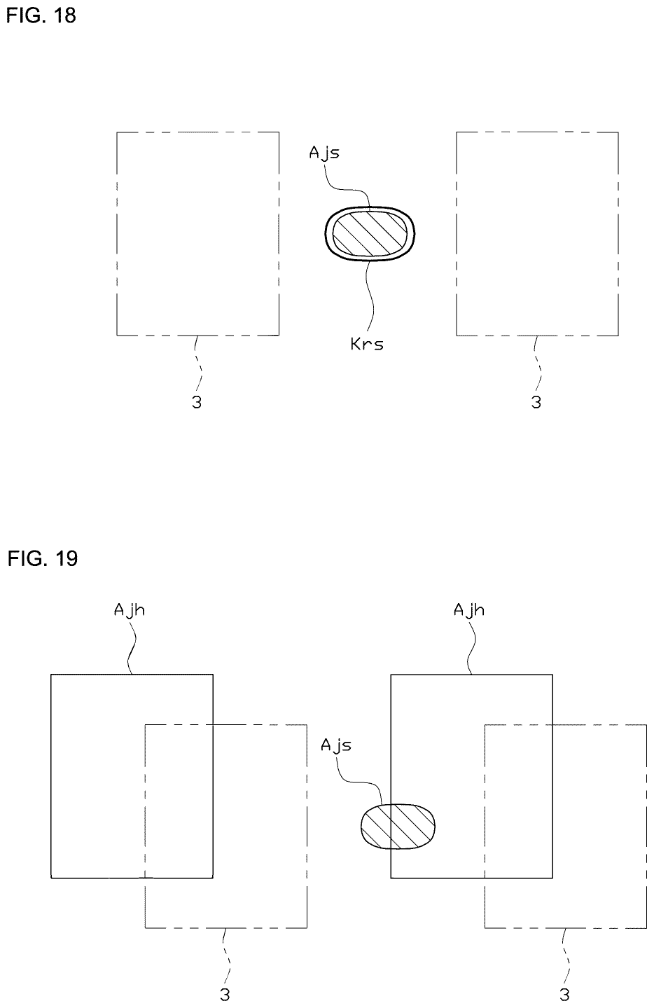

The determination module 337d performs a determination process that performs good/poor quality judgment with regard to the adhesive 6, based on the entire area Ajs specified by the entirety specification module 337c. The determination process generates an adhesive inspection window Krs (shown in FIG. 18) that shows a reference inspection range of the adhesive 6, based on the design data or the manufacturing data stored in the inspection information storage portion 342b. The adhesive inspection window Krs serves as a good/poor quality judgment criterion with regard to the dimensions and the position of the adhesive 6 alone. The adhesive inspection window Krs has a shape similar to the shape of a plane area occupied by the adhesive 6 on the data and denotes an area where the center coordinates of the adhesive inspection window Krs are identical with the center coordinates of the plane area. The adhesive inspection window Krs is set to have slightly larger dimensions than the dimensions of the plane area occupied by the adhesive 6 on the data.

The determination process subsequently uses the adhesive inspection window Krs to determine whether or not the entire area Ajs is adequate. More specifically, the determination process determines whether or not a ratio of an area other than the entire area Ajs to the area of the adhesive inspection window Krs exceeds a predetermined reference value that is set in advance. When the ratio is equal to or less than the reference value, the application state of the adhesive 6 alone is determined as “good”. When the ratio is greater than the reference value, the application state of the adhesive 6 alone is determined as “poor”.

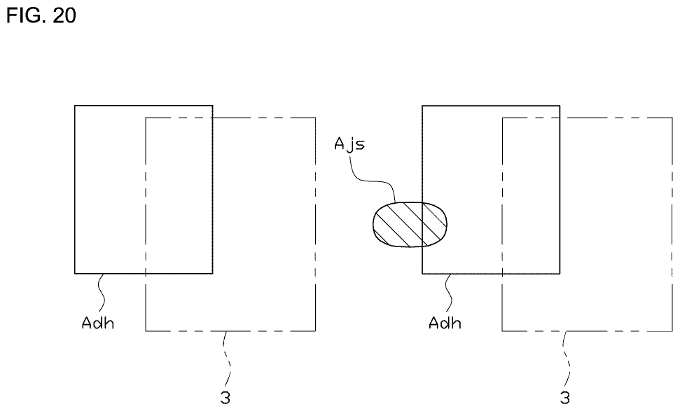

The determination process also determines whether or not a positional relationship between the adhesive 6 and the solder 4 is adequate. More specifically, the determination process calculates an area of an overlap between the solder area Ajh and the entire area Ajs and determines whether the area of this overlap exceeds a predetermined area reference value that is set in advance (as shown in FIG. 19). When the area of the overlap exceeds the area reference value and it is thus determined that the positional relationship between the adhesive 6 and the solder 4 is inadequate, the determination process determines that the application state of the adhesive 6 is “poor” in terms of the positional relationship to the solder 4. In this case, the application state of the solder 4 is also determined to be “poor”. When the area of the overlap is equal to or less than the area reference value and it is thus determined that the positional relationship between the adhesive 6 and the solder 4 is adequate, on the other hand, the determination process determines that the application state of the adhesive 6 is “good” in terms of the positional relationship to the solder 4.

Additionally, the determination process determines whether or not a positional relationship between the adhesive 6 and the electrode portion area Adh is adequate. More specifically, the determination process calculates an area of an overlap between the entire area Ajs and the electrode portion area Adh and determines whether the area of this overlap exceeds a predetermined area reference value that is set in advance (as shown in FIG. 20). When the area of the overlap exceeds the area reference value and it is thus determined that the positional relationship between the adhesive 6 and the electrode portion area Adh is inadequate, the determination process determines that the application state of the adhesive 6 is “poor” in terms of the positional relationship to the planned location area of the electrode portion 5a. When the area of the overlap is equal to or less than the area reference value and it is thus determined that the positional relationship between the adhesive 6 and the electrode portion area Adh is adequate, on the other hand, the determination process determines that the application state of the adhesive 6 is “good” in terms of the positional relationship to the planned location area of the electrode portion 5a.

When all the results of the respective determinations described above are “good”, the determination process determines that the application state of the adhesive 6 is “good”. When the result of at least any one of the respective determinations described above is “poor”, on the other hand, the determination process determines that the application state of the adhesive 6 is “poor”.

According to the embodiments, the good/poor quality judgment with regard to the adhesive 6 described above is performed for all the portions of the adhesive 6 provided on the board 1. When any of the respective portions of the adhesive 6 is determined as “poor”, the control device 33 determines that the board 1 is “defective”. In the case where the board 1 is determined as “defective”, the board 1 is discharged to the defective storage unit described above by the branch device.

As described above in detail, the configuration of the embodiments specifies the center portion area Ajsa by using the hue H and specifies the foot portion area Ajsb by using the saturation S. This configuration separately specifies the center portion area Ajsa and the foot portion area Ajsb, which respectively have different optical characteristics, by the different specification procedures. This specifies both the areas with high accuracy and thereby enables an area occupied by the adhesive 6 (the entire area Ajs) to be specified with the higher accuracy. As a result, this improves the accuracy with regard to the good/poor quality judgment of the adhesive 6.

The center portion specification module 337a extracts the red color area from the hue image in the case of specifying the center portion area Ajsa. This accordingly enables the center portion area Ajsa of the red-color adhesive 6 that is used generally and widely to be specified more accurately and more readily.

Furthermore, the foot portion specification module 337b extracts the low saturation area from the saturation image in the case of specifying the foot portion area Ajsb. This accordingly enables the foot portion areas Ajsb (the foot portion 6b) that is affected by the green resist area 7 as the foundation to have the relatively low saturation, to be specified more accurately and more readily.

Moreover, the foot portion specification process performs the process of excluding the area with regard to the silkscreen 8. This more reliably prevents the area with regard to the silkscreen 8 from being mistakenly specified as the area with regard to the adhesive 6 (the foot portion area Ajsb or the entire area Ajs). This accordingly enables the area with regard to the adhesive 6 to be specified more accurately.

The present disclosure is not limited to the description of the above embodiments but may be implemented, for example, by configurations described below. The present disclosure may also be naturally implemented by applications and modifications other than those illustrated below.
(a) According to the embodiments described above, the center portion specification module 337a is configured to extract the red color area from the hue image based on the RGB luminance image in the case of specifying the center portion area Ajsa. According to a modification, however, the center portion specification module 337a may be configured to extract an area of higher luminance than a predetermined luminance reference value from a red luminance image based on the RGB luminance image in the case of specifying the center portion area Ajsa. In this modification, the center portion specification process is performed as described below.

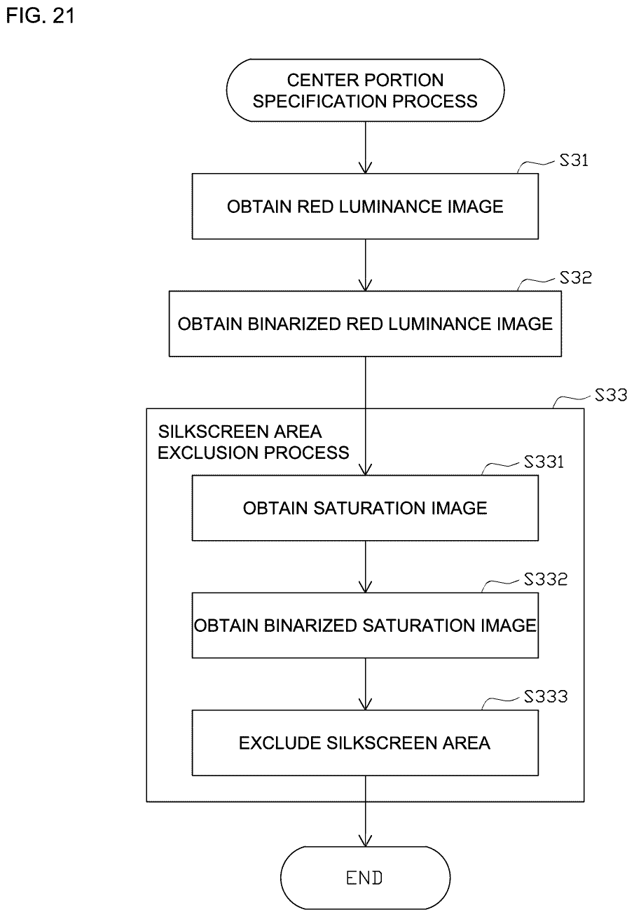

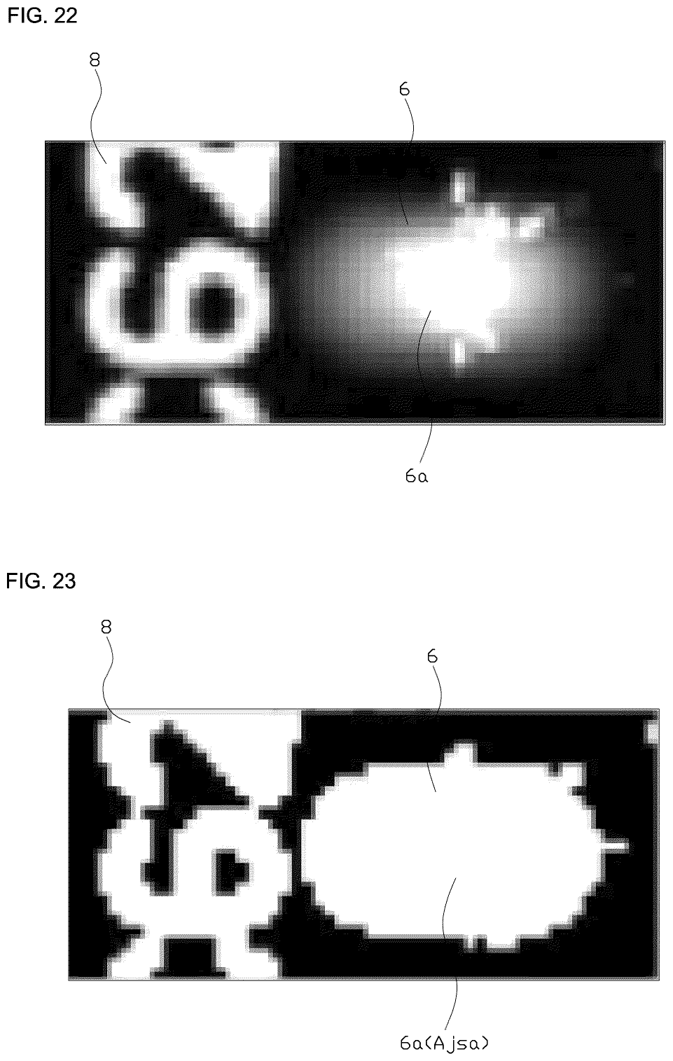

As shown in FIG. 21, at step S31, the center portion specification process first uses the RGB luminance image obtained by the camera 322 to obtain a red luminance image with regard to the inspection target area of the board 1. More specifically, the center portion specification process extracts only the parameter values of R among the respective parameter values with regard to R, G and B in the RGB luminance image, so as to obtain the red luminance image. FIG. 22 illustrates one example of the red luminance image. In the red luminance image, the center portion 6a having relatively high parameter values of R is relatively bright. In the red luminance image, the silkscreen 8 is also relatively bright.

At step S32, the center portion specification process subsequently processes the red luminance image by a binarization process using a predetermined luminance reference value and thereby obtains a binarized red luminance image. FIG. 23 illustrates one example of the binarized red luminance image. The binarized red luminance image is a black and white image including 0 (bright part) and 1 (dark part). In this image, not only the center portion 6a but the silkscreen 8 is a bright part.

At step S33, the center portion specification process subsequently performs a silkscreen area exclusion process to exclude an area with regard to the silkscreen 8 from the binarized red luminance image. The silkscreen area exclusion process first obtains a saturation image (shown in FIG. 12) based on the RGB luminance image, in order to extract an area of especially low saturations from the RGB luminance image at step S331. In the saturation image, while the center portion 6a or the like having relatively high saturation is bright, the silkscreen 8 having relatively low saturation is dark.

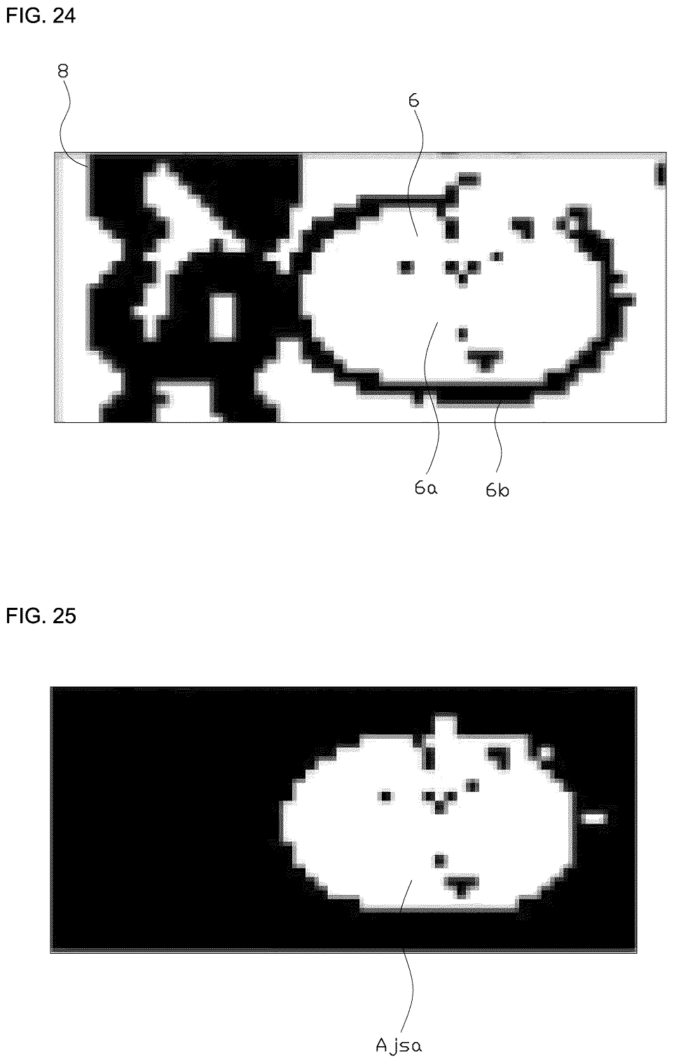

At step S332, the silkscreen area exclusion process subsequently processes the obtained saturation image by a binarization process using a predetermined saturation reference value and thereby obtains a binarized saturation image. FIG. 24 illustrates one example of the binarized saturation image. The binarized saturation image is a black and white image including 0 (bright part) and 1 (dark part) and is stored in the image storage portion 342a. In the binarized saturation image, while the center portion 6a is a bright part, the silkscreen 8 is a dark part.

At step S333, the silkscreen area exclusion process calculates a logical AND of the obtained binarized red luminance image and the obtained binarized saturation image, so as to exclude the area with regard to the silkscreen 8 from the binarized red luminance image. The center portion specification process accordingly obtains a center portion extraction image (shown in FIG. 25). This center portion extraction image is a black and white image including 0 (bright part) and 1 (dark part), like the center portion extraction image of the embodiments described above. The bright part of the center portion extraction image is specified as the center portion area Ajsa.
(b) The above embodiments and (a) descried above are configured to perform the process of excluding the area with regard to the silkscreen 8 in the case of specifying the center portion area Ajsa or in the case of specifying the foot portion area Ajsb. A modification may, however, be configured to perform a process of excluding the area with regard to the silkscreen 8 in the case of specifying the entire area Ajs.

In this modification, the center portion specification process does not need to perform the process of excluding the area with regard to the silkscreen 8, unlike the configuration of (a) described above. The center portion specification module 337a accordingly obtains a binarized red luminance image (shown in FIG. 23) that includes the center portion area Ajsa and the area with regard to the silkscreen 8 and that is allowed to specify the center portion area Ajsa. The foot portion specification module 337b obtains a binarized reverse saturation image (shown in FIG. 14) that includes the foot portion area Ajsb and the area with regard to the silkscreen 8 and that is allowed to specify the foot portion area Ajsb.

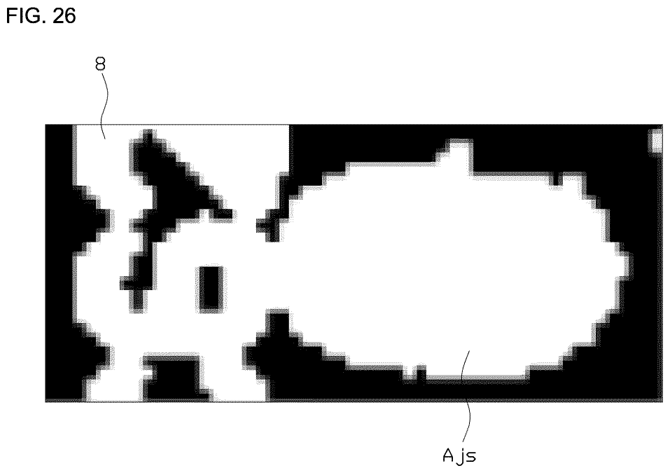

The entirety specification module 337c then calculates a logical AND of the binarized red luminance image obtained by the center portion specification module 337a and the binarized reverse saturation image obtained by the foot portion specification module 337b and thereby obtains an adhesive and silkscreen extraction image. FIG. 26 illustrates one example of the adhesive and silkscreen extraction image. This image includes not only the entire area Ajs but the area with regard to the silkscreen 8. The entirety specification module 337c performs a process of excluding the area with regard to the silkscreen 8 (silkscreen area exclusion process), in order to specify the entire area Ajs alone.

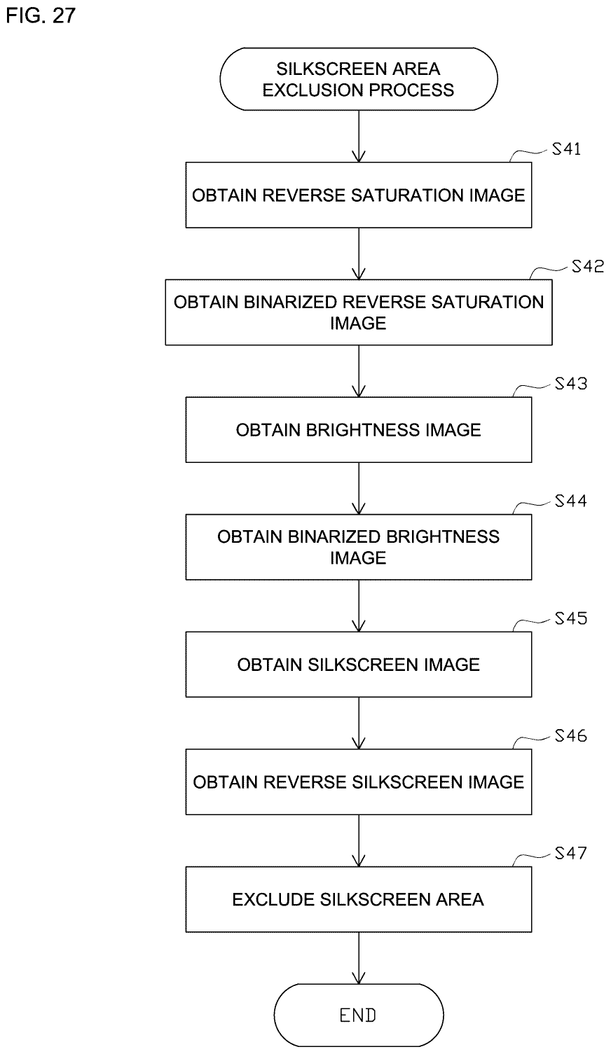

The silkscreen area exclusion process first performs a process of extracting only the area with regard to the silkscreen 8. As shown in FIG. 27, the silkscreen area exclusion process first obtains a reverse saturation image (shown in FIG. 13) based on the RGB luminance image at step S41 and obtains a binarized reverse saturation image (shown in FIG. 14) at step S42. In the binarized reverse saturation image, the area with regard to the silkscreen 8 is a bright part.

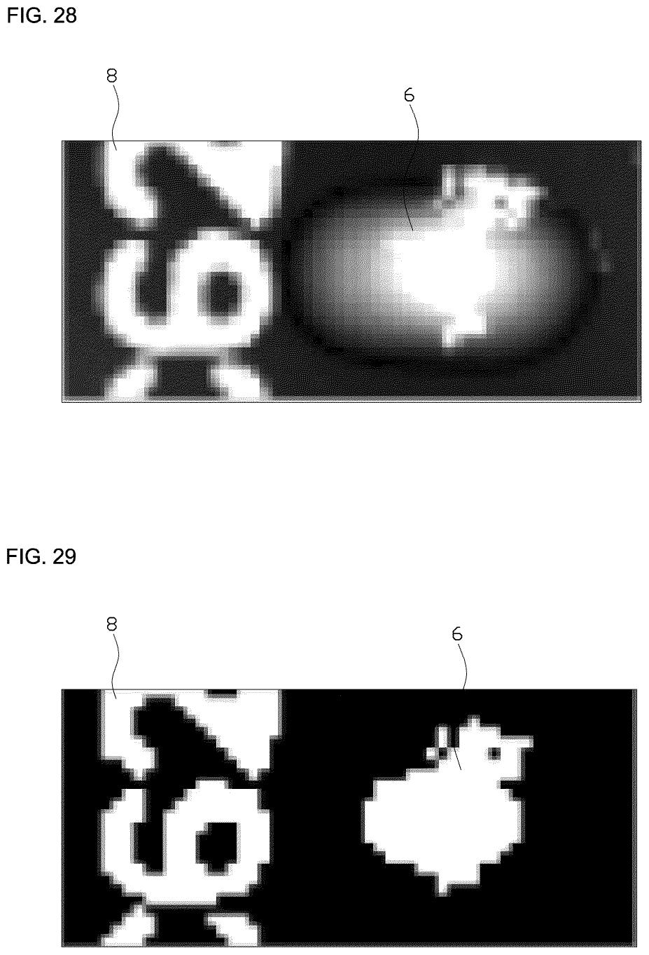

The silkscreen area exclusion process subsequently obtains a brightness image (shown in FIG. 28) based on the RGB luminance image at step S43. At step S44, the silkscreen area exclusion process then processes the brightness image obtained at step S43 by a binarization process using a predetermined brightness reference value and thereby obtains a binarized brightness image (shown in FIG. 29). The brightness reference value is set, based on the brightnesses of the center portion 6a and the silkscreen 8 in the brightness image. In the binarized brightness image, the area with regard to the silkscreen 8 is a bright part, as in the binarized reverse saturation image. The processing of steps S43 and 44 may be performed prior to or in parallel with the processing of steps S41 and S42.

At step S45, the silkscreen area exclusion process subsequently calculates a logical AND of the binarized reverse saturation image obtained at step S42 and the binarized brightness image obtained at step S44 and thereby obtains a silkscreen image (shown in FIG. 30) with extraction of only the area with regard to the silkscreen 8. In the silkscreen image, a process of expanding the area with regard to the silkscreen 8 may be performed additionally. This additional process enables the area with regard to the silkscreen 8 to be more reliably excluded.

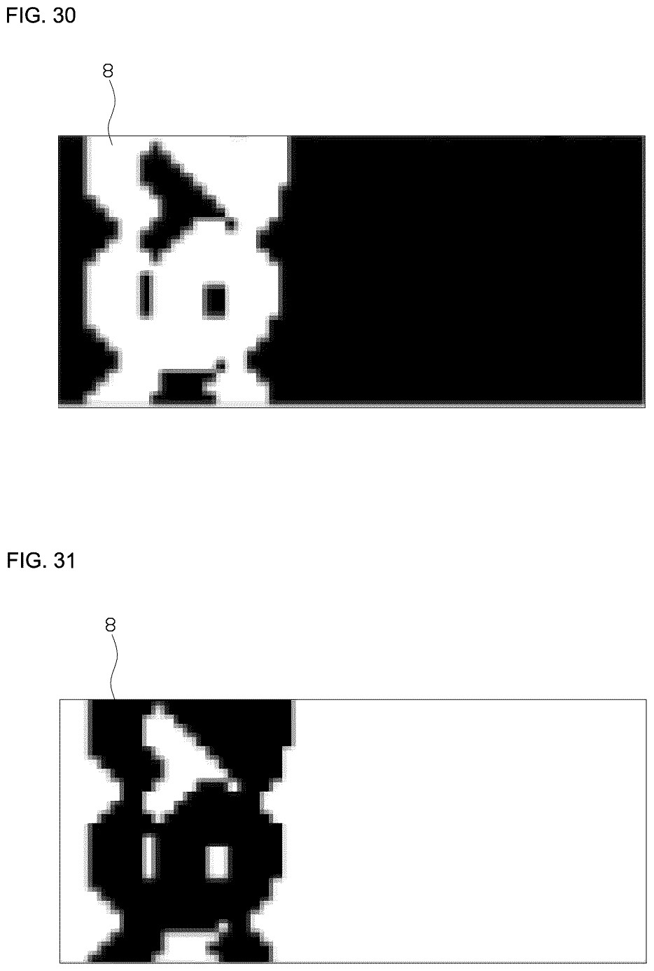

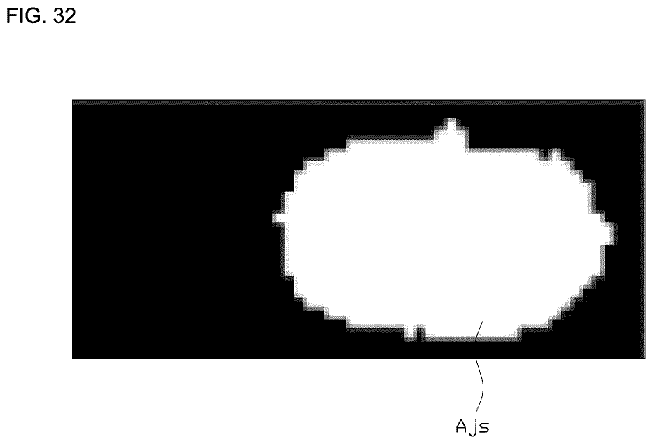

At steps S46 and S47, the silkscreen area exclusion process excludes the area with regard to the silkscreen 8 from the adhesive and silkscreen extraction image, so as to obtain an adhesive extraction image including only the entire area Ajs. At step S46, the silkscreen area exclusion process first reverses the silkscreen image obtained at step S45 to obtain a reverse silkscreen image (shown in FIG. 31). In the reverse silkscreen image, the area with regard to the silkscreen 8 is a dark part. At step S47, the silkscreen area exclusion process calculates a logical AND of the adhesive and silkscreen extraction image and the reverse silkscreen image, so as to exclude the area with regard to the silkscreen 8 from the adhesive and silkscreen extraction image. The silkscreen area exclusion process accordingly obtains an adhesive extraction image (shown in FIG. 32). The entirety specification module 337c specifies a bright part of the obtained adhesive extraction image as the entire area Ajs.
(c) The exclusion of the area with regard to the silkscreen 8 in the case of the white silkscreen 8 is described in the above embodiments and (b) described above. In the case of the yellow silkscreen 8, the area with regard to the silkscreen 8 may be excluded by a procedure described below. The procedure obtains a hue image from the RGB luminance image and specifies (extracts) a yellow area in this hue image, so as to obtain a silkscreen image that extracts the area with regard to the silkscreen 8. The procedure then uses this silkscreen image (for example, calculates a logical AND of the adhesive and silkscreen extraction image described above and a reverse image of this silkscreen image) to exclude the area with regard to the silkscreen 8.
(d) According to the embodiments described above, the center portion specification module 337a (the center portion specification process) does not perform the process of excluding the area with regard to the silkscreen 8 in the case of specifying the center portion area Ajsa from the hue image. According to a modification, however, the silkscreen area exclusion process described above in (a) or in (b) may be performed in the case of specifying the center portion area Ajsa from the hue image.
(e) According to the embodiments described above, the foot portion specification module 337b is configured to exclude the area with regard to the silkscreen 8 from the binarized reverse saturation image in the case of specifying the foot portion area Ajsb.

According to a modification, however, the foot portion specification module 337b may be configured to specify (extract) an area that is adjacent to the center portion area Ajsa specified by the center portion specification module 337a or an area that is located around the center portion area Ajsa, out of the area with regard to the foot portion 6b and with regard to the silkscreen 8 (bright parts in FIG. 14) in the binarized reverse saturation image, as the foot portion area Ajsb. The configuration of this modification also enables the foot portion area Ajsb to be specified more accurately and more readily.
(f) The above embodiments and (a) described above are configured to specify the center portion area Ajsa by using the hue H or the red luminance. A modification may, however, be configured to specify the center portion area Ajsa by using the value V (for example, the brightness image as shown in FIG. 28). This is because the center portion 6a is expected to have relatively large differences in the value V, in the hue H, and in the red luminance (the parameter value of R among the respective parameter values with regard to R, G, and B) from the foot portion 6b and the resist area 7.

The above embodiments are configured to specify the foot portion area Ajsb by using the saturation S. A modification may, however, be configured to specify the foot portion area Ajsb by using the hue H (for example, the hue image as shown in FIG. 9). This is because the foot portion 6b is expected to have relatively large differences in the saturation S and in the hue H from the center portion 6a and the resist area 7.

In the case of using the hue H to respectively specify the center portion area Ajsa and the foot portion area Ajsb, a modification may be configured to use a different hue reference value for every specification object and specify the center portion 6a (the center portion area Ajsa) or the foot portion 6b (the foot portion area Ajsb). Accordingly, employing the different specification procedures for specifying the center portion area Ajsa and for specifying the foot portion area Ajsb means employing different conditions for specifying the center portion area Ajsa and for specifying the foot portion area Ajsb, on the basis of the different optical characteristics of the center portion area Ajsa and the foot portion area Ajsb: for example, employing the different elements (the hue H, the saturation S, the value V and the red luminance) for specifying the center portion area Ajsa and for specifying the foot portion area Ajsb; or employing the different reference values for specifying the center portion area Ajsa and for specifying the foot portion area Ajsb.
(g) According to the embodiments described above, the respective ring lights 321a, 321b and 321c are configured to radiate the white light. According to a modification, however, the respective ring lights 321a, 321b and 321c may be configured to respectively radiate the red light, the blue light and the green light (i.e., different color lights). In this modification, the camera 322 may be configured by a monochromatic camera to take an image of the printed circuit board 1 every time the light is radiated sequentially from each of the ring lights 321a, 321b and 321c and thereby obtain three different images. The hue image, the saturation image and the like may be obtained, based on these three different images. In these three different images, the parameter value with regard to R (red color), the parameter value with regard to G (green color) and the parameter value with regard to B (blue color) are respectively set corresponding to each of the pixels. Accordingly, these three different images correspond to the “RGB luminance image”.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1 . . . printed circuit board (board), 6 . . . adhesive, 7 . . . resist area, 8 . . . silkscreen, 13 . . . board inspection device, 322 . . . camera (imaging unit), 337a . . . center portion specification module (center portion specification unit), 337b . . . foot portion specification module (foot portion specification unit), 337c . . . entirety specification module (entirety specification unit), 337d . . . determination module (determination unit), Ajs . . . entire area, Ajsa . . . center portion area, Ajsb . . . foot portion area

What is claimed is:

1. Aboard inspection device configured to inspect an adhesive applied on a board, the board inspection device comprising:
an imaging device that takes an image of an area on the board where the adhesive is applied;
a central processing unit (CPU) that:
specifies, by a first procedure, a center portion area of the adhesive in the image obtained by the imaging device;
specifies, by a second procedure, a foot portion area of the adhesive around the center portion area in the image;
specifies an entire area of the adhesive based on the center portion area and the foot portion area; and
based on the entire area of the adhesive, determines whether a quality of the adhesive is good or poor, wherein
the board has a green resist area,
the adhesive has a red color and is applied on the resist area, and
when specifying the foot portion area, the CPU extracts, an area of lower saturation than a predetermined saturation reference value from a saturation image based on the image.

2. The board inspection device according to claim 1, wherein
when specifying the center portion area, the CPU extracts an area of the red color from a hue image based on the image, or extracts an area of higher luminance than a predetermined luminance reference value from a red luminance image based on the image.

3. The board inspection device according to claim 1, wherein
the CPU executes a process of excluding an area of a silkscreen provided on the board, from at least one of the center portion area, the foot portion area, and the entire area that are eventually specified.

4. The board inspection device according to claim 2, wherein
the CPU executes a process of excluding an area of a silkscreen provided on the board, from at least one of the center portion area, the foot portion area, and the entire area that are eventually specified.

5. A board inspection method of inspecting an adhesive applied on a board, the board inspection method comprising:
an imaging process of taking an image of an area on the board where the adhesive is applied;
a center portion specification process of specifying, by a first procedure, a center portion area of the adhesive in the image obtained by the imaging process;
a foot portion specification process of specifying, by a second procedure, a foot portion area of the adhesive around the center portion area in the image;
an entirety specification process of specifying an entire area of the adhesive based on the center portion area and the foot portion area; and
a determination process of determining, based on the entire area of the adhesive, whether a quality of the adhesive is good or poor, wherein
the board has a green resist area,
the adhesive has a red color and is applied on the resist area, and
the foot portion specification process extracts, when specifying the foot portion area, an area of lower saturation than a predetermined saturation reference value from a saturation image based on the image.
